(19) United States
(12) Patent Application Publication
(10) Pub. No.: US 2007/0298529 A1
(43) Pub. Date: Dec. 27, 2007

(54) Semiconductor light-emitting device and method for separating semiconductor light-emitting devices

(75) Inventors: Susumu Maeda, Aichi-ken (JP); Ryuichiro Sasaki, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: TOYODA GOSEI, CO., LTD., Nishikasugai-gun (JP)

(21) Appl. No.: 11/806,068

(22) Filed: May 29, 2007

(30) Foreign Application Priority Data
Oct. 13, 2006 (JP) 2006-279511
May 31, 2006 (JP) 2006-152023

(51) Int. Cl. H01L 21/00

(52) U.S. Cl. 438/33; 257/E21.002

(57) ABSTRACT

The invention provides a method for separating semiconductor light-emitting devices formed on a substrate. In the method, a pulse laser beam having a pulse width less than 10 ps in a substrate is focused on the substrate, to thereby cause multi-photon absorption in the substrate. Through multi-photon absorption, a groove is formed through the pulse laser beam along a split line predetermined on a surface of the substrate, the groove being substantially continuous in the direction of the predetermined split line. In addition, internal structurally changed portions are formed through the pulse laser beam at a predetermined depth of the substrate on a predetermined split face, the structurally changed portions being discontinuous in the direction of the predetermined split line. Subsequently, an external force is applied to thereby form a split face along the continuous groove and the discontinuous internal structurally changed portions, whereby the semiconductor light-emitting devices are separated from one another

### BACKGROUND OF THE INVENTION

1. Field of the Invention

The present invention relates to a method for separating semiconductor light-emitting devices formed on a substrate, to thereby yield individual semiconductor light-emitting devices, the method including dividing or splitting a wafer formed of the substrate and the devices provided thereon. The present invention is particularly effective for separating, for example, group III nitride-based compound semiconductor light-emitting devices. As used herein, the term “wafer” collectively refers to substrates which are provided through performing so-called wafer processes (e.g., washing, diffusion ion-implantation, thin film growth, epitaxial growth, photolithography, and formation of electrode) on a transparent substrate.

2. Background Art

Hitherto, a variety of methods have been proposed for splitting a wafer having group III nitride based compound semiconductor light-emitting devices on a sapphire substrate, to thereby yield individual semiconductor light-emitting devices. Generally, most of these methods employ combination of formation of scribe lines (grooves) by means of a scriber and dicing by means of a dicer blade. However, such methods have drawbacks in that operating cost cannot be reduced to a certain level or lower, due to use of expendable scribers and dicer blades.

In recent years, for splitting or cutting a plate-like object, there have been proposed melt-cutting techniques employing laser beam radiation and cutting techniques employing, as a starting point, internal molten or structurally changed portions provided through laser beam radiation. Among such laser-radiation-based techniques, Japanese Patent Application Laid-Open (kokai) No. 2005-288503 discloses a technique employing a pulse laser beam having a sub-millisecond pulse width; i.e., a nanosecond pulse laser beam, and Japanese Patent No. 3283265 and Japanese Patent Application Laid-Open (kokai) No. 2004-268309 disclose techniques employing a pulse laser beam having a sub-picosecond pulse width; i.e., a femtosecond pulse laser beam.

Meanwhile, light-emitting diodes, inter alia, blue-light LEDs employing a group III nitride light-emitting layer, are required to be modified so that light extraction efficiency (external quantum efficiency) is enhanced to increase total light emission. Through the interface between a transparent substrate and a light-emitting layer, only incident light entering at an angle equal to or smaller than the critical angle is extracted. Thus, in order to enhance external quantum efficiency, for example, the surface of the substrate opposite the semiconductor-layer-formed surface is coarsened (see, for example, Japanese Patent Application Laid-Open (kokai) No. 2001-217467).

When a substrate is thoroughly melt-cut through laser beam radiation, the width of a melt-affected portion, which is a side surface of the device, becomes large. The split face may also be baked (discolored). In both cases, light extraction efficiency is impaired, since the split face, which is a side surface of the device and which is intrinsically transparent, is no longer transparent, and absorbs a predominant light emitted from the light-emitting device. In one solution of the problem, Japanese Patent Application Laid-Open (kokal) No. 11-163403 discloses that grooves are formed in a substrate to a predetermined depth from a device-formed surface or the opposite surface. In some countermeasures, such grooves are formed in a dashed-line-pattern through a pulse laser beam. However, the width of the melt-affected portion on a split face (a side face of the device) is problematic, and even when a nanosecond pulse laser beam is employed as a pulse laser beam, the melt-affected portion of the separated device has a large area in a side face of the device, resulting in problematic absorption of emitted light. Meanwhile, Japanese Patent Application Laid-Open (kokal) No. 11-163403 also discloses that splitting of a substrate can be facilitated only when the thickness of the substrate is reduced to 100 μm or less. Notably, in the disclosure, the splitting is performed not by the mediation of shallow grooves formed through laser beam radiation but by the mediation of combination of laser-radiation-formed shallow grooves with grooves having a thickness of 100 μm formed by means of a dicer or laser-radiation.

In Japanese Patent Application Laid-Open (kokai) No. 2004-268309, radiation of a femtosecond laser beam is employed in order to generate “stress for causing splitting.” Therefore, it is essential that separation grooves are provided through a technique other than laser beam radiation. In this case, if the aforementioned expendable scriber is employed, operating cost cannot be reduced.

Recently, light-emitting devices including a rectangular light-emitting face having a short side of 250 μm or less (corresponding to a length equal to or less than twice the thickness of the sapphire substrate) are more and more often employed as, for example, a backlight of a liquid crystal display of a mobile phone. Since such light-emitting devices are separated at very small intervals, split faces must be formed so as to be perpendicular to a substrate surface as designed, and slanted split faces are not allowable.

In the light-emitting diode disclosed in Japanese Patent Application Laid-Open (kokai) No. 2001-217467, the surface of the substrate opposite the semiconductor-layer-formed surface is coarsened, whereby external quantum efficiency is enhanced. However, the thus-produced chips can only be subjected to the flip-chip bonding process in which the semiconductor-layer-formed surface is affixed on a mounting frame. Even if the chips are subjected to the face-up chip bonding process in which the surface of the substrate opposite the semiconductor-layer-formed surface is affixed on a frame having a parabolic mirror, external quantum efficiency cannot be enhanced, since a non-light extraction surface of the substrate is coarsened. In other words, external quantum efficiency of the aforementioned light-emitting diodes depends on the mounting orientation, which is a problem to be solved.

In addition, in order to coarsen the surface of a transparent substrate opposite the semiconductor-layer-formed surface, additional steps such as a photolithographic step and wet etching must be performed. These steps increase an environmental load and, therefore, decrease throughput. As a result, light-emitting device production cost increases.

### SUMMARY OF THE INVENTION

In view of the foregoing, an object of the present invention is to provide a method for splitting a substrate having a thickness of about 200 μm on which semiconductor light-emitting devices are formed. The present inventors have successfully found such a method without employing an expendable scriber or dicer blade and have accomplished the present invention.

Another object of the present invention for solving the problems involved in the aforementioned conventional semiconductor light-emitting devices is to provide, at low production cost, semiconductor light-emitting devices which can be produced in any mounting orientation. Yet another object of the invention is to provide a method for splitting a wafer into device chips.

Accordingly, in a first aspect of the present invention, there is provided a method for separating semiconductor light-emitting devices formed on a substrate, the method comprising focusing a pulse laser beam having a pulse width less than 10 ps in said substrate, to thereby cause multi-photon absorption in the substrate;

forming a surface structurally changed portion by means of the pulse laser beam along a split line predetermined on a surface of the substrate;

forming internal structurally changed portions through the pulse laser beam at a predetermined depth of the substrate on a predetermined split face, the internal structurally changed portions being discontinuous in a direction of the predetermined split line; and

applying an external force to thereby form a split face along the surface structurally changed portion and the discontinuous internal structurally changed portions, whereby the semiconductor light-emitting devices are separated from one another.

In the present invention, the term “structurally changed portion” conceptually includes a melt-affected portion.

In the method for separating semiconductor light-emitting devices according to the first aspect of the invention, the surface structurally changed portion may be discontinuously separated in plural sections along said split line.

In the method for separating semiconductor light-emitting devices according to the first aspect of the invention, the surface structurally changed portion may be substantially continuous to form a groove along said split line.

In the method for separating semiconductor light-emitting devices according to the first aspect of the invention, two or more rows of the discontinuous internal structurally changed portions may be formed along the depth direction of the substrate.

In the method according to the first aspect of the invention, additional internal structurally changed portions may be formed along the split line through a pulse laser beam such that the additional internal structurally changed portions are connected to the surface structurally changed portion in a depth direction, and subsequently, an external force is applied.

In the method according to the first aspect of the invention, the laser beam radiated may be a linearly polarized laser beam having an electric field component parallel to the predetermined split face or an elliptically polarized laser beam exhibiting a trajectory of the electric field component that forms an ellipse having a longer axis parallel to the predetermined split face.

In the method according to the first aspect of the invention, the laser beam may be radiated through an objective lens having a numerical aperture of 0.5 or more.

The substrate may be a sapphire substrate.

The structurally changed portions each may include a head portion which is formed at a focal site of the pulse laser beam and which has a diameter parallel to a substrate surface of 1.5 μm or more, and a leg portion which extends from the head portion along the radiated pulse laser beam through filamentation and which has a diameter parallel to a substrate surface of 0.8 μm or more.

In a second aspect of the present invention, there is provided a method for separating semiconductor light-emitting devices, including splitting a wafer into individual semiconductor light-emitting device chips, the wafer comprising a transparent substrate having a first surface, and a second surface parallel to the first surface, and a semiconductor layer containing a light-emitting layer and deposited on the first surface of the transparent substrate, wherein the method comprises

a first internal processing step including

causing a pulse laser beam having a wavelength ensuring optical transparency with respect to the wafer to enter the wafer through the first or second surface serving as an incident face by the mediation of a condensing lens, while the focus of the condensing lens is adjusted such that a waist, which is a pulse laser beam focused portion, is present in the wafer;

shifting the optical axis of the pulse laser beam relative to the incident face and along an imaginary split line predetermined on the wafer such that waists formed from the pulse beams provided by the pulse laser beam are spatially separated from one another; and

at every incidence of the pulse beam of the pulse laser beam on the incident face, embrittling a portion of the wafer corresponding to the waist through multi-photon absorption, to thereby form discontinuous light-induced embrittled portions; and

a grooving step including

adjusting the focus of the condensing lens such that a waist formed by the pulse laser beam is present in a surface portion of the incident face of the wafer;

shifting the optical axis of the pulse laser beam relative to the incident face and along the split line such that waists formed from the pulse beams provided by the pulse laser beam are spatially connected to or overlapped with one another; and

at every incidence of the pulse beam of the pulse laser beam on the incident face, embrittling a portion of the wafer corresponding to the waist through multi-photon absorption, to thereby form a continuous groove, wherein

each of the semiconductor light-emitting device chips has a split face provided with indents/protrusions.

In the internal processing step, the waists are spatially separated from one another along a split line in the wafer such that the waists are arrayed in a dashed-line-like manner. Light-induced embrittled portions are provided at the portions corresponding to the waists in a wafer. Thus, the light-induced embrittled portions are arrayed on the split face and spatially separated from one another along the split line so as to form a dashed-line-like pattern. In a split face (side wall) of each of the separated semiconductor light-emitting devices, light-induced embrittled portions serve as indents in which the substrate material is absent, whereas the portion provided between two light-induced embrittled portions serve as protrusions in which the substrate material is present. Since each split face (i.e., side wall) that is perpendicular to a light extraction face of the semiconductor light-emitting device is provided with indents/protrusions, the total light extraction efficiency can be enhanced by the thus-formed side wall (split face). In addition, split faces are provided with indents/protrusions during a separation step in which the wafer is split to form individual semiconductor light-emitting device chips. Therefore, no additional step of enhancing light extraction efficiency is needed, and semiconductor light-emitting devices can be produced at low cost.

As used herein, the term “light-induced embrittling” refers to adiabatic processing of a portion of a material (waist portion), where a picosecond to femtosecond short pulse laser beam is focused.

The method for separating semiconductor light-emitting devices according to the second aspect of the invention may further comprise a second internal processing step including adjusting the focus of the condensing lens such that a waist is present between the light-induced embrittled portions formed in the first internal processing step and the incident face;

shifting the optical axis of the pulse laser beam relative to the incident face and along an imaginary split line predetermined on the wafer such that waists formed from the pulse beams provided by the pulse laser beam are spatially separated from one another; and

at every incidence of the pulse beam of the pulse laser beam on the incident face, embrittling a portion of the wafer corresponding to the waist through multi-photon absorption, to thereby form discontinuous light-induced embrittled portions.

In the above method, a split face is provided with two rows of indents/protrusions portions. Therefore, light-emitting devices separated through the semiconductor light-emitting device separation method exhibit higher light extraction efficiency from side walls serving as split faces.

In the method for separating semiconductor light-emitting devices according to the second aspect of the invention, the condensing lens may has a numerical aperture of 0.3 or more.

When the numerical aperture is 0.3 or more, waists are drastically narrowed, and exclusively provide light-induced embrittled portions with a small indent width. As a result, extraction efficiency is enhanced. In addition, when the numerical aperture is 0.3 or more, the grooving step may be performed first, followed by the internal processing step.

In the method for separating semiconductor light-emitting devices according to the second aspect of the invention, the focus of the condensing lens may be adjusted such that the upper portions of the light-induced embrittled portions formed in the second internal processing step and the bottom of the groove formed in the grooving step may be connected to one another.

In the above method, a wafer can be reliably split by external force along predetermined split lines to thereby produce light-emitting device chips, since the upper portions of the light-induced embrittled portions formed in the second internal processing step and the bottom of the groove formed in the grooving step are connected to one another.

In a third aspect of the present invention, there is provided a semiconductor light-emitting device, including a transparent substrate having a first surface, and a second surface parallel to the first surface, and a semiconductor layer containing a light-emitting layer and deposited on the first surface, wherein the semiconductor light-emitting device separated from a wafer has a split face provided with indents/protrusions.

Since split faces are provided with indents/protrusions, the total light extraction efficiency can be enhanced by the split faces. In addition, since light is extracted through the split faces; i.e., side walls of a semiconductor light-emitting device, any mounting orientation can be selected.

According to the present invention, surface structurally changed portion/portions are formed on a surface of a wafer, and internal structurally changed portions are provided in the wafer, by means of a femtosecond laser beam. When an external force is applied to the wafer, split faces are formed from the surface structurally changed portion/portions and the internal structurally changed portions, whereby semiconductor light-emitting devices are separated from one another. Since formation of structurally changed portions through a femtosecond laser beam is a non-thermal process, a molten portion is not principally formed. Through focusing a femtosecond laser beam on a surface of a substrate so as to form the surface structurally changed portion/portions or grooves, and regulating a scanning speed of the substrate or a laser apparatus so as to modify the radiation pitch in the scanning direction, considerably shallow structurally changed portions can be formed.

Thus, split faces can be formed such that, in each face, a shallow surface structurally changed portion/portions or groove provided at a surface of the substrate, and the internal structurally changed portions (having a diameter of several μm as measured on a surface parallel to the substrate) are connected. By virtue of this structure, a breaking tool such as a cutter is preferably employed instead of an expendable breaking tool. Through provision of structurally changed portions, there can be realized a method for separating semiconductor light-emitting devices by means of a femtosecond laser beam, the method employing light-absorbing portions such as structurally changed portions (having considerably small areas as measured on a device split face). The internal structurally changed portions are not necessarily provided in a continuous manner along a split line to form one single portion, and large numbers of structurally changed portions are preferably formed in a predetermined split face.

The present invention can be applied to a substrate having a thickness of 70 μm or more and less than 500 μm. In addition, pulse laser beam radiation allows wafers to be processed for a very short period of time, and the thus-treated wafers can immediately be split. Therefore, the total processing time can be remarkably shortened as compared with, for example, a separation method employing a scriber and a dicer blade in combination. According to the present invention, split faces which are perpendicular to a substrate surface can readily be provided, thereby enhancing device production yield.

A plurality rows of the discontinuous internal structurally changed portions are preferably provided along the depth direction of the substrate. This structure facilitates formation of cracks from the surface of surface structurally changed portion/portions or groove via a plurality rows of the internal structurally changed portions, whereby high-precision device separation is successfully performed.

When additional internal structurally changed portions are further provided through a pulse laser beam such that the portions are continuous or discontinuous along the predetermined split line and connected to the continuous or discontinuous surface structurally changed portions, followed by applying an external force, higher-precision device separation is successfully performed.

The laser beam radiation is preferably performed by a linearly polarized laser beam having an electric field component parallel to the predetermined split face or an elliptically polarized laser beam exhibiting a trajectory of the electric field component that forms an ellipse having a longer axis parallel to the predetermined split face. Elliptical polarization is divided into linear polarization in which an electric field component is parallel to a predetermined split face and a circular polarization. In other words, by virtue of the electric field component parallel to a predetermined split face, the split face is provided with structurally changed portions of wider areas.

When laser beam radiation is performed through a lens having a large numerical aperture, so-called focal depth is reduced, whereby extension of a focused portion (spot) in a depth direction can be prevented. Therefore, structurally changed portions having a small length in the depth direction of the substrate can be formed through multi-photon absorption.

Particularly, the present invention can be applied to a substrate which is difficult to split at high precision by other methods; e.g., a sapphire substrate.

Each of the structurally changed portions is provided at the focused portions. Since the structurally changed portion has a leg portion which is formed through filamentation and which extends in the depth direction, the wafer can be reliably split, keeping low light absorption of the device.

In the internal processing step, the waists (laser-focused portions) are spatially separated from one another along a split line in the wafer such that the waists are arrayed in a dashed-line-like manner. Light-induced embrittled portions are provided at the portions corresponding to the waists in a substrate. Thus, the light-induced embrittled portions are arrayed on the split face and spatially separated from one another along the split line so as to form a dashed-line-like pattern. The light-induced embrittled portions serve as indents in which the substrate material is absent, whereas the portion provided between two light-induced embrittled portions serve as protrusions in which the substrate material is present. According to the separation method of the present invention, each split face (i.e., side wall) of the separated semiconductor light-emitting device chips is provided with indents/protrusions. Therefore, the total light extraction efficiency can be enhanced by the thus-formed side walls (split faces). In addition, since split faces are provided with indents/protrusions during a wafer splitting step, no additional step of enhancing light extraction efficiency is needed, and semiconductor light-emitting devices can be produced at low cost.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1 is a cross-section of a wafer schematically showing the method of the present invention;

FIG. 2 is an SEM image of structurally changed portions provided through the method of the present invention;

FIGS. 3A to 3E are cross-sections showing the steps of the splitting method of the present invention;

FIG. 4 is an SEM image of a split face formed in Example 1, with a portion of the image being enlarged;

FIG. 5A is an SEM image of a split face formed in Example 1, with a portion of the image being enlarged;

FIG. 5B is an SEM image of a split face formed in Comparative Example 1, with a portion of the image being enlarged;

FIGS. 6A and 6B are SEM images of a split face formed in Comparative Example 2;

FIG. 6C is an SEM image of a split face formed in Example 1;

FIG. 7 is a schematic cross-section of an LED structure in which a light-emitting diode chip is mounted on a support, the cross-section being provided for demonstrating the method according to Embodiment 2 of the present invention;

FIG. 8 is a schematic view for demonstrating internal processing included in the splitting method of the present invention;

FIG. 9 is a partial broken cross-section cut along the line A-A of FIG. 8;

FIG. 10A is an enlarged schematic view of a region in the vicinity of the beam waist shown in FIG. 9;

FIG. 10B is a cross-section profile (C-C) of FIG. 10A;

FIG. 11A is a schematic view of waist regions for demonstrating two internal processing steps;

FIG. 11B is a cross-section profile (E-E) of FIG. 11A;

FIG. 12 is a schematic view for demonstrating a grooving step included in the splitting method of the present invention;

FIGS. 13A and 13B are an enlarged partial broken cross-section cut along the line B-B of FIG. 12;

FIG. 14 is a perspective view of the wafer after grooving;

FIG. 15 is a schematic view of a wafer for showing the principle of the splitting method of the present invention;

FIG. 16 is a schematic view for showing process conditions of the Example under which a sapphire substrate is split according to the splitting method of the present invention;

FIG. 17 is a micrographic image of a split face of a sapphire substrate provided in the Example according to the splitting method of the present invention; and

FIG., 18 is a block diagram of a splitting apparatus for carrying out the internal processing step and the grooving step included in the splitting method of the present invention.

### DETAILED DESCRIPTION OF PREFERRED EMBODIMENTS

Embodiment 1 of the invention will next be described.

The femtosecond laser beam employed in the present invention may be generated by means of, for example, an apparatus disclosed in Japanese Patent No. 3283265. Needless to say, any other known apparatuses may also be employed.

No particular limitation is imposed on the dimensions of structurally changed portions. However, each portion preferably has a spot diameter, as measured on a surface parallel to the substrate surface, of 1 to 10 μm, more preferably 1 to 4 μm, still more preferably 1.5 to 3 μm. The spot diameter is controlled by tuning energy, laser beam diameter, or numerical aperture of the employed objective lens. In addition, the spot length (in the depth direction) is also determined. In a structurally changed portion, a leg portion may be formed before the formation of a spot. The leg portion is formed through self-focusing action, called filamentation. The thus-formed leg portions of the structurally changed portions are preferred, in that the leg portions serve as starting portions of cracking during application of an external force. Since the leg portions do not further expand, high-precision split faces are obtained.

In Example 1 described hereinbelow, structurally changed portions had a spot diameter as measured on a plane parallel to the substrate surface of about 2.5 μm, a depth-direction spot length of about 5 μm, and a leg portion length of about 15 μm. Pulse energy (energy per pulse) is preferably 0.1 to 10 μJ, more preferably 0.5 to 5 μJ, still more preferably 1 to 3 μJ. When the objective lens has a large numerical aperture, the beam diameter can readily be reduced, whereby the spot diameter as measured on a plane parallel to the substrate surface can be reduced. Furthermore, when the objective lens has a large numerical aperture, focal depth can be reduced, whereby the spot length can be shortened. The numerical aperture of the objective lens is 0.4 or more, preferably 0.5 or more, more preferably 0.6 or more.

Notably, the numerical aperture does not necessarily exceed 1, and is more preferably 0.8 or less. The spacing in the depth direction between two structurally changed portions (length between the bottom most level of a first structurally changed portion including leg portions and the uppermost level of a second structurally changed portion under the first portion) is preferably 1 μm to 50 μm. According to the present invention, each structurally changed portion has small dimensions. Therefore, when the spacing in the depth direction between two structurally changed portions is in excess of 50 μm, the substrate is difficult to split, whereas when the spacing in the depth direction is intended to be less than 1 μm, the number of rows of structurally changed portions required to split one substrate must be increased, resulting in a long production time. Therefore, the spacing in the depth direction between two structurally changed portions is preferably 2 μm to 30 μm, more preferably 5 μm to 10 μm.

The pitch between structurally changed portions which are discontinuous in the split line direction is preferably controlled so that one structurally changed portion is not connected to the neighboring portion. From another viewpoint, the spacing is preferably controlled so that two structurally changed portions adjacent to each other are sufficiently split through cracking. In this regard, when the maximum diameter of a structurally changed portion as measured on a plane parallel to the substrate surface is 1, the pitch between structurally changed portions is preferably 1.2 to 8, more preferably 1.5 to 6, still more preferably 2 to 4. In Example 1 hereinbelow, the structurally changed portion had a spot diameter as measured on a plane parallel to the substrate surface of about 2.5 μm. Accordingly, the pitch is preferably 5 μm (spacing between structurally changed portions of about 2.5 μm).

The surface structurally changed portion/portions may be continuous or discontinuous when surface structurally changed portion/portions is continuous, the portion/portions make a groove. The surface structurally changed portion/portions which is along the split line direction preferably has a depth of about 0.5 to 30 μm. When the surface structurally changed portion/portions is excessively shallow, splitting is difficult, whereas when it is excessively deep, the area of the side walls increases. Thus, the depth of the surface structurally changed portion/portions is more preferably 1 to 15 μm. The laser beam is preferably a linearly polarized laser beam, which is polarized in the split line direction.

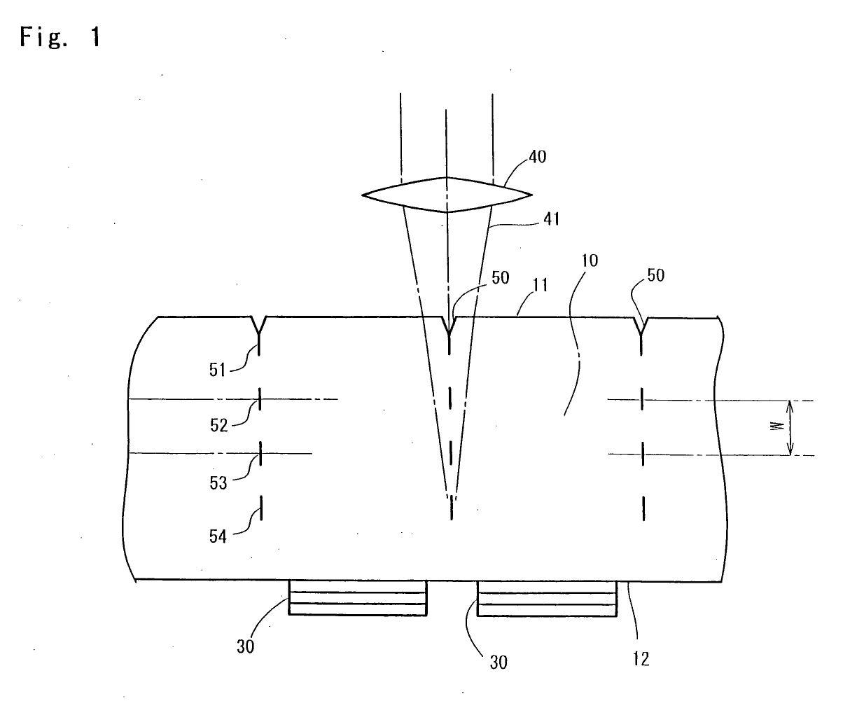

FIG. 1 is a cross-section of a wafer for schematically showing the method of separating semiconductor light-emitting devices of the present invention. As shown FIG. 1, on a surface 12 of a sapphire substrate 10, group III nitride-based compound semiconductor light-emitting devices 30 are formed through epitaxial growth, forming electrodes, and other steps. Through the other surface 11 of the sapphire substrate 10, a femtosecond pulse laser beam 41 is focused by the mediation of an objective lens 40 at a predetermined depth of the sapphire substrate 10. The laser beam radiation causes multi-photon absorption at the focus portion, whereby internal structurally changed portions 51, 52, 53, and 54 are provided, as well as a groove 50 as the surface structurally changed portion/portions. FIG. 1 is a cross-section which is perpendicular to a predetermined split face (normal to FIG. 1 in the forward-backward direction), and to surfaces 11 and 12 of the sapphire substrate 10. A split line is an intersection between the predetermined split face and the surface 11 of the sapphire substrate 10, which line is continued in the forward-backward direction with respect to FIG. 1. The groove 50 is formed along the split line. The structurally changed portion 51 is connected to the groove 50 and extends in the split line direction. The structurally changed portion 52 is not connected to the structurally changed portions 51 and 53 in the depth direction of the sapphire substrate 10, and is provided in a discrete manner along the split line direction. Similarly, the structurally changed portions 53 and 54 are not connected to the structurally changed portions 52 and 53, respectively, in the depth direction of the sapphire substrate 10, and are provided in a discrete manner along the split line direction. The profiles of the structurally changed portions 52 to 54 on a split face are shown hereinbelow.

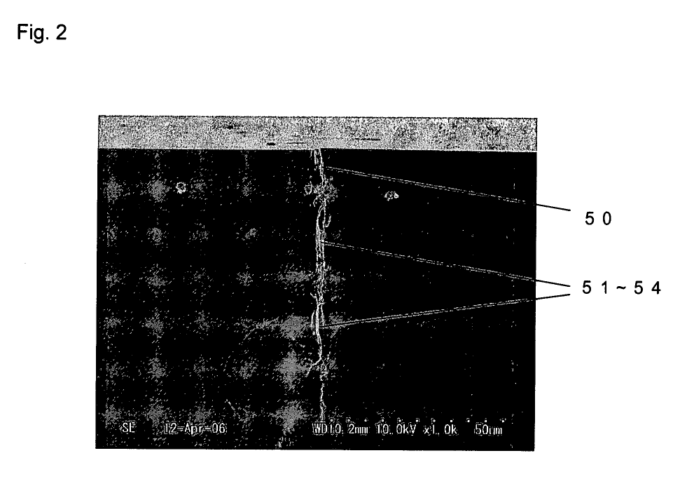

FIG. 2 is an SEM image showing the groove 50 and the structurally changed portions 51 to 54 provided by a femtosecond pulse laser beam according to the present invention. As is clear from FIG. 2, the provided structurally changed portions have a considerably small width.

### EXAMPLE 1

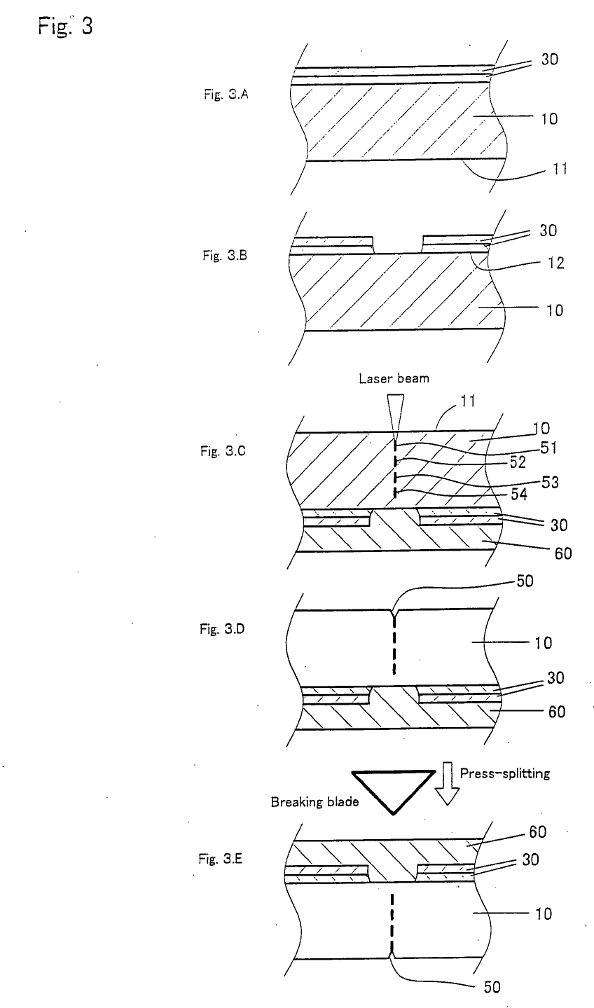

FIGS. 3A to 3E show the steps included in the method for separating semiconductor light-emitting devices according to one specific example of the present invention. As shown in FIG. 3A, a group III nitride-based compound semiconductor light-emitting device 30 was formed on one surface 12 of the sapphire substrate 10 having a thickness of 140 μm through epitaxial growth, formation of electrodes, and other steps. Subsequently, an unnecessary portion near a split line for separating the group III nitride-based compound semiconductor light-emitting device 30 was removed through etching (FIG. 3B).

Next, an adhesive tape 60 was attached to the surface of the sapphire substrate 10 on which the group III nitride-based compound semiconductor light-emitting devices 30 had been formed, and the femtosecond pulse laser beam was scanned on the surface 11, which is a backside of the sapphire substrate 10, whereby the groove 50 and the structurally changed portions 51 to 54 were formed.

The femtosecond pulse laser beam employed was controlled to the following conditions: a wavelength of 1 μm, a pulse width of 500 fs, a pulse frequency of 100 kHz, and a pulse energy of 1.5 μJ/pulse. The linear polarization component was adjusted so as to be parallel to a predetermined split face. The employed objective lens had a numerical aperture of 0.65. The above laser beam was scanned on the surface 11 of the sapphire substrate 10. The scanning speed was adjusted to 250 mm/s when the groove 50 and the structurally changed portion 51 were formed and to 500 mm/s when the structurally changed portions 52 to 54 were formed. The focus was adjusted to 0 μm from the surface 11 during formation of the groove 50, 5 μm during formation of the structurally changed portion 51, 25 μm during formation of the structurally changed portion 52, 55 μm during formation of the structurally changed portion 53, and 85 μm during formation of the structurally changed portion 54. Notably, the structurally changed portion 54, the structurally changed portion 53, the structurally changed portion 52, the groove 50, and the structurally changed portion 51 were sequentially formed in this order (FIGS. 3C and 3D).

Then, the wafer was inverted, and an external force was applied by means a breaking blade to the surface of the sapphire substrate 10 on which the group III nitride compound semiconductor light-emitting device 30 had been formed and the adhesive tape 60 had been attached, whereby the wafer was split to provide individual devices (FIG. 3E). Each split face coincided with the predetermined split face, and was perpendicular to the surfaces 11 and 12 of the sapphire substrate 10. As compared with the case of device separation by means of a dicer and a scriber, the thus-formed split faces were found to have a higher flatness. Through employment of the procedure, a thick substrate can be split.

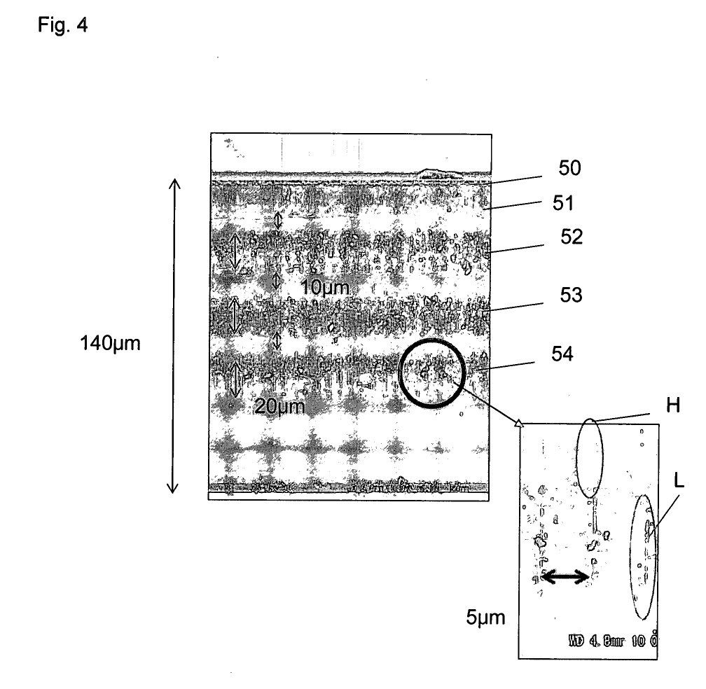

FIG. 4 is an SEM image of a split face. As shown in FIG. 4, the structurally changed portions 52 to 54 each having a width of 20 μm were clearly arranged in the depth direction with a spacing of 10 μm. An individual structurally changed portion provided per pulse included a head portion H (diameter: about 2.5 μm, length: about 5 μm) and a leg portion L (diameter: about 0.6 μm, length: about 15 μm). During splitting the substrate, cracks propagated from one structurally changed portion to neighboring portions. The pitch between two structurally changed portions adjacent to each other in the split line direction was 5 μm. The leg portion having a length of about 15 μm was formed through “filamentation,” which occurred through focusing a laser beam by the mediation of the formed head portion having a diameter of about 2.5 μm and a length of about 5 μm. Cracking in the depth direction was found to occur with a very high face precision after development of cracks in the split line direction.

### COMPARATIVE EXAMPLE 1

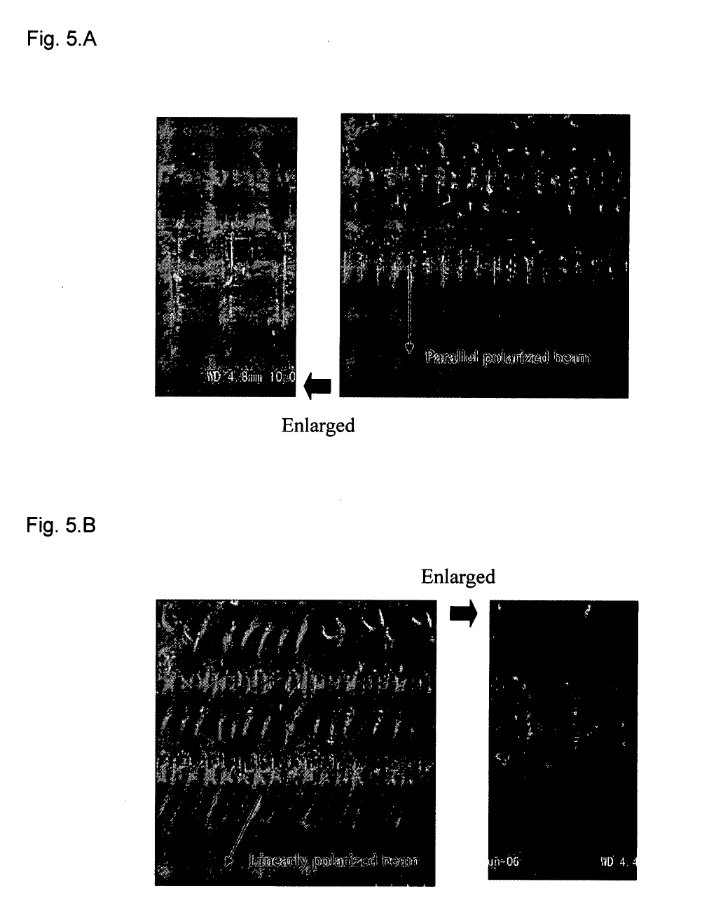

The separation procedure of Example 1 was repeated, except that the polarization direction of the pulse laser beam was changed such that a linear polarization component was included in the direction perpendicular to the split face. FIG. 5B is an SEM image of the split face. The SEM image of FIG. 5A is an enlarged image of FIG. 4. When a linear polarization component was included in the direction perpendicular to the split face, the width of a structurally changed portion in the split line direction was relatively small, and no cracking occurred along the split line direction from the structurally changed portions. Therefore, through employment of a pulse laser beam having a linear polarization component parallel to the split face, splitting of a substrate can be readily attained by a smaller external force.

### COMPARATIVE EXAMPLE 2

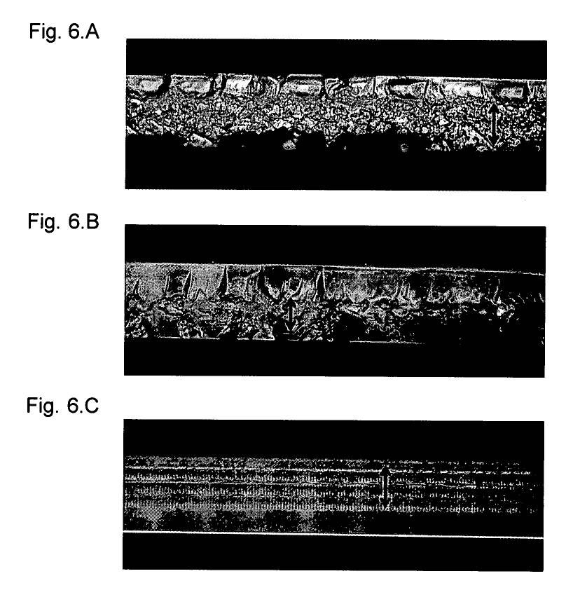

Numerical aperture of the objective lens was changed to 0.2 or 0.4. Cross-sections of a sapphire substrate cut by the laser beam under the above conditions are shown in FIGS. 6A and 6B. In Comparative Example 2, only one row of structurally changed portions was provided. When the objective lens had a numerical aperture of 0.2, a row of structurally changed portions was formed to a thickness ≧½ the thickness of the substrate (FIG. 6A), whereas when the objective lens had a numerical aperture of 0.4, a row of structurally changed portions was formed to a thickness about ⅓ the thickness of the substrate (FIG. 6B). In both cases (numerical aperture of 0.2 and 0.4), the provided laser beam had poor precision, and the formed split faces had poor flatness. In addition, since a large amount of portions are removed during laser-splitting, the numerical apertures (0.2 and 0.4) cannot be applied to separation of small device chips. Furthermore, undesired cracks were generated. As compared with FIG. 6C (reduced image of FIG. 4), the objective lens was found to have a numerical aperture 0.5 or more in order to attain sufficient focusing.

Embodiment 2 of the invention will next be described.

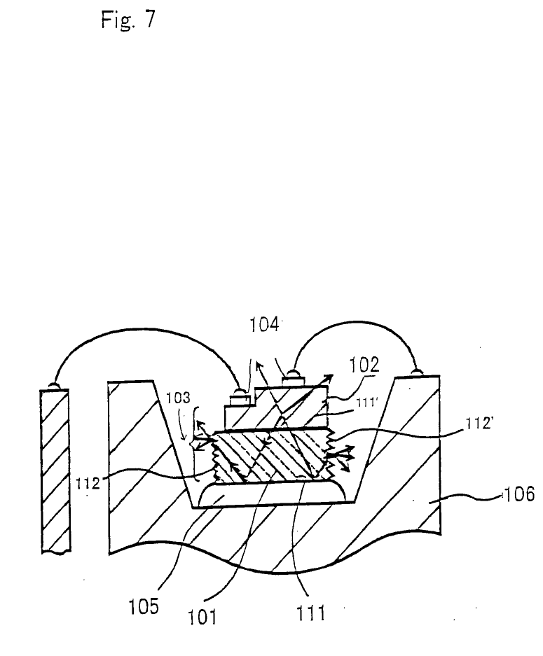

Embodiment 2 is directed to a method for separating light-emitting diode chips according to present invention. FIG. 7 shows a configuration of an LED in which a light-emitting diode chip is mounted on a support and which is processed according to one embodiment of the present invention. Notably, FIG. 7 is a schematic view, and lateral/vertical dimensions and layer thicknesses do not reflect actual values. Actually, a transparent substrate 101 had a thickness of about some 100 μm, and a semiconductor layer 102 which is a stacked layer including a light-emitting layer had a thickness of about 1 μm. A light-emitting diode chip 103 includes the transparent substrate 101 and the semiconductor layer 102. The employed transparent substrate 101 was made of sapphire. On a first surface 111′ of the sapphire substrate 101, the semiconductor layer 102, which is a stacked nitride semiconductor layer including a light-emitting layer, was formed, while a second surface 111 of the transparent substrate 101 was affixed to the bottom of a cup of the support 106 by means of an adhesive 105. In FIG. 7, the support 106 was a lead frame. Split faces 112 and 112′ of the wafer and split faces 113 and 113′ of the wafer (not illustrated, but present along the forward-backward direction, all split faces orthogonally intersecting the first and second surfaces 111′ and 111 of the transparent substrate 101), were provided with indents/protrusions. On the semiconductor layer 102 formed from a nitride semiconductor, a positive electrode 104 serving as an Ohmic electrode and a negative electrode 104 were formed. The Ohmic electrode 104 was connected to a lead frame 106 through wire bonding.

No particular limitation is imposed on the material of the transparent substrate 101, and any substrate may be employed, so long as the substrate allows a semiconductor crystal to grow for forming the semiconductor layer 102. Examples of employable substrates include transparent insulating substrates made of an oxide such as sapphire or spinel, and transparent substrates made of a semiconductor such as zinc oxide or gallium nitride. The transparent substrate 101 made of such a material transmits the light emitted from the semiconductor layer 102 formed on the first surface 111′. As used herein, the term “transparent” refers to a transparency which allows transmission of a large proportion of the light emitted from a light-emitting diode; i.e., 80% or more, desirably 90% or more, in terms of amount of emitted light.

The semiconductor layer 102, formed on the first surface 111′ of the transparent substrate 101, has, for example, a double-hetero structure in which an n-type GaN contact layer, an n-type AlGaN cladding layer, an InGaN active layer, a p-type AlGaN cladding layer, a p-type GaN layer, and other layers have been stacked in this order. Alternatively, the semiconductor layer 102 may have a single-hetero structure having a pn junction, a homo structure, or a MIS structure having a light-emitting layer as an i-layer.

Provision of indents/protrusions to split faces 112 and 112′ of the transparent substrate 101 and two split faces intersecting split faces 112 and 112′ may be performed through wet-etching, photolithography, or a similar technique. However, as mentioned hereinbelow, indents/protrusions are preferably provided during splitting through the method of splitting a wafer according to the present invention. Through employment of this manner, an additional indents/protrusions forming step is not needed, thereby reducing chip production cost.

The adhesive 105 for bonding the second surface 111 of the transparent substrate 101 to the support 106 may be formed from a polymer material. Preferably, the adhesive is a conductive material containing a metal, since the material effectively transfers heat of the light-emitting diode chip 103 to the support 106. Examples of conductive material adhesives employed in the invention include a silver paste and an In paste.

The support 106 may be made of a variety of materials. Examples of the support include metallic supports such as a lead frame and a stem; and ceramic supports such as an alumina substrate. The light-emitting diode chip 103 is mounted on the second surface 111 of the aforementioned support 106 by the mediation of the adhesive 105. In other words, the diode chip is mounted in a face-up manner.

As shown in FIG. 7 and indicated by arrows, in the LED processed in the present invention, the light emitted from the transparent semiconductor layer 102 transmits through the transparent sapphire substrate 101 and reaches four faces; i.e., the split faces 112 and 112′ and two split faces orthogonally intersecting the split faces 112 and 112′. When a split face is a mirror surface, the incident light entering at an incident angle greater than a critical angle cannot emit to the outside. However, according to the present invention, since split faces are provided with indents/protrusions, the incident light entering at an incident angle greater than the critical angle can also emit to the outside without being bound to critical angle conditions at the faces provided with indents/protrusions. Therefore, light extraction efficiency (external quantum efficiency) can be enhanced.

The light-emitting diode chip separated in the present invention exhibits high light extraction efficiency through the split faces. Thus, mounting type is not limited to the face-up manner as shown in FIG. 7. Even when the light-emitting diode chip employs a flip-chip bonding structure in which electrodes 104 are downwardly sustained toward the support 106, emitted light can be effectively extracted to the outside.

Next, the method for splitting a wafer into individual chips will be described. The wafer includes a sapphire substrate on which a semiconductor layer containing a light-emitting layer has been stacked, and which has been patterned so as to provide separate light-emitting devices.

<Internal Processing Step>

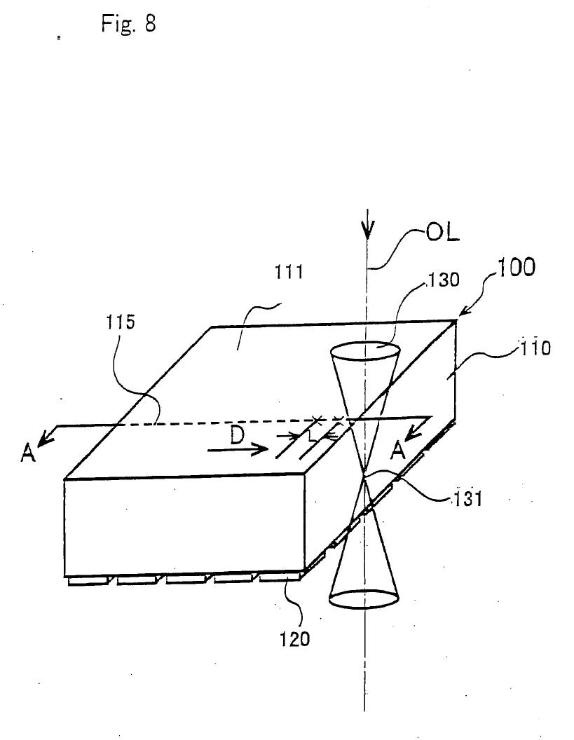

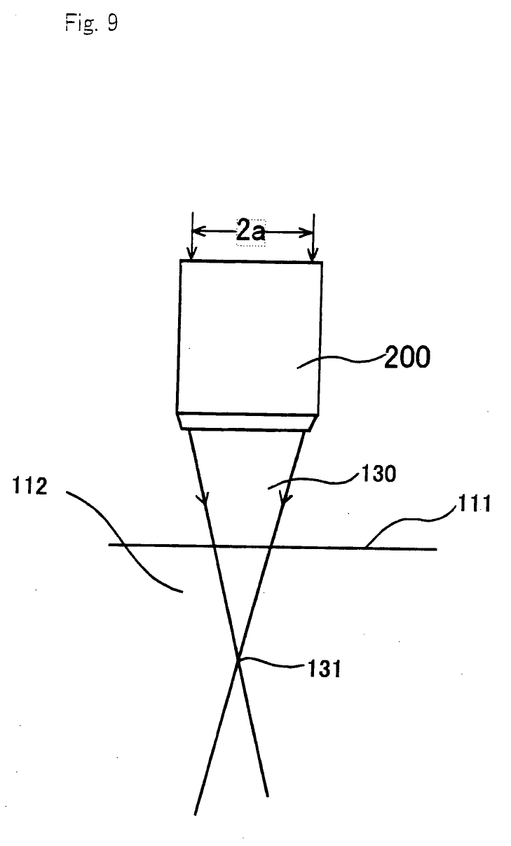

With reference to FIGS. 8 to 11, the internal processing step will be described. In FIG. 8, a wafer is a sapphire substrate 110 on which a patterned semiconductor layer 120 has been formed. On a second surface 111 on which no semiconductor layer 120 has been stacked, a split line 115 is predetermined as indicated by a dashed line. The split line 115 is predetermined such that the line passes through the semiconductor layer 120 on the first surface 111′ on which the semiconductor layer 120 has been stacked. The employed laser beam has such a wavelength as not to cause linear absorption by the sapphire substrate 110 included in the wafer 100. The employed laser apparatus is, for example, a femtosecond laser apparatus based on the rare-earth-doped mode-lock fiber laser. In the Example, a short pulse laser beam 130 having a pulse width of 400 fs was employed. As shown in FIG. 8, the short pulse laser beam 130 is focused by means of a condensing lens 200 as shown in FIG. 9 and enters the second surface 111 of the sapphire substrate 110. As shown in FIG. 9, the laser beam 130 perpendicularly enters the second surface 111 and is focused by means of the condensing lens 200 such that a waist 131 of the laser beam 130 is present inside the substrate 101. Prior to carrying out the internal processing step, an optical bench is slightly shifted along the Z-axis by means of a drive member of the processing apparatus (FIG. 18) mentioned hereinbelow, whereby the spacing between the second surface 111 of the sapphire substrate 110 and the condensing lens 200 is adjusted. Through the procedure, the beam waist 131 of the laser beam 130 is realized at a predetermined depth from the second surface 111 of the substrate 110.

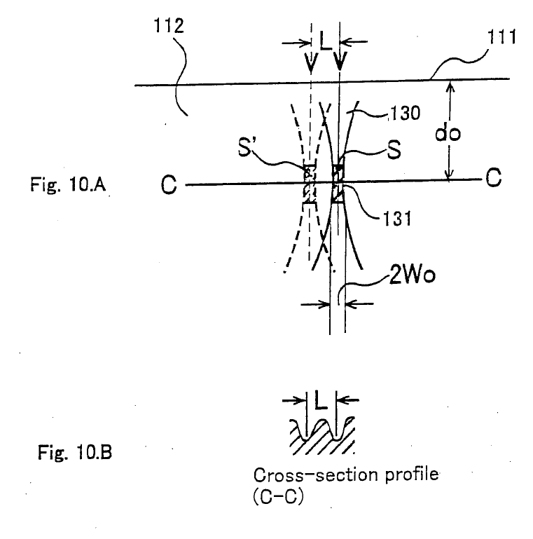

The predetermined position do, in the direction perpendicular to the second surface 111 (the depth direction), of the waist 131 of the short pulse laser beam 130 focused by means of the condensing lens 200 is predetermined through the following procedure (FIG. 10). Firstly, the focus and position of the condensing lens 200 are adjusted so that the light of an illumination source passing through the condensing lens 200 forms a spot (focused light portion) on the second surface 111 of the substrate 110. Subsequently, the condensing lens 200 is shifted by a predetermined distance d toward the second surface 111 of the substrate 110. The predetermined shift distance d is represented by the following equation:
d=d0/n(λ) (1);
wherein d0 represents a predetermined distance, and n(λ) represents the refractive index of the substrate 110 with respect to a laser beam 130 of a wavelength of λ.

In a specific case in which a waist 131 is predetermined in a substrate 110 having a thickness of 200 μm at a depth from the second surface 111 of 80 μm, d is 45.7 μm as calculated from d0 (80 μm) and n(λ) (1.75). Thus, the focus of the condensing lens 200 on the second surface 111 is shifted to a depth of 80 μm from the substrate surface by shifting the condensing lens 200 by 45.7 μm toward the second surface 111.

At the thus-determined focus, as shown in FIG. 8, the optical axis OL of the short pulse laser beam 130 is moved relatively with respect to the second surface 111 along the direction of the split line 115 predetermined on the second surface 111 of the sapphire substrate 110, toward the arrow D, at a predetermined internal processing velocity Vin. In FIG. 9, which is a partial broken cross-section cut along the line A-A of FIG. 8, the split line 115 is parallel to the cross-section shown in FIG. 9. As shown in FIG. 8 and indicated by X, pulse beams of the short pulse laser beam 130 enter, through the second surface 111 of the substrate 110 with a spacing L, waists S and S′ (laser beam radiated portions) shown in FIG. 10. The distance L is given by the following equation:
L=Vin/R (2);
wherein R represents the pulse repetition frequency of the laser beam 130, and Vin represents internal processing velocity.

FIGS. 10A and 10B are enlarged schematic views of beam waist portions shown in FIG. 9. A continuous line pair represents the shape of a beam waist provided by a pulse beam at a certain time, and a broken line represents the shape of a beam waist provided by a pulse beam of the subsequent frequency. As shown now in FIG. 10A, one pulse beam of the short pulse laser beam 130, which has been focused by a condensing lens (not illustrated), forms a waist portion S in the sapphire substrate 110 from the depth of d0. When the waist portion S is irradiated with a light beam having a high power density of, for example, 5 TW/cm², multi-photon absorption is induced, leading to light-induced embrittlement. When a pulse width is 400 fs, a power density of 5 TW/cm² corresponds to a fluence of 2 J/cm².

When the laser beam is a single-mode beam, the spot diameter (2W0) of a beam waist is represented by the following equation:
2W0=(4λ/π)(f/2a) (3);
wherein f represents the focal length of the condensing lens 200, and 2a represent the beam diameter of the laser beam 130 entering the condensing lens.

The aforementioned predetermined internal processing velocity Vin is determined so that waist spots or waist portions S and S′ adjacent to each other are spatially separated. In order to satisfy the condition, the relationship L>2W0 must be satisfied, and Vin>2W0·R is required as calculated from equation (2).

In the case where the waist portions S and S′ separated as shown in FIG. 10A, and a wafer is split by driving a wedge to the split line 115 as mentioned hereinbelow, a cross-section shown in FIG. 10A is given, if Vin>2W0·R is satisfied.

In a C-C section in FIG. 10A (plane parallel to the second surface 111), as shown in FIG. 10B, light-induced embrittled portions S and S′ assume the form of indents (portions where substrate material is absent), and the portion between S and S′ assumes the form of a protrusion (portion where substrate material is present). In FIG. 10A, only two light-induced embrittled portions S and S′ provided through pulse beams are shown. However, needless to say, since the optical axis OL of the short pulse laser beam 130 is relatively moved along the split line 115 at a internal processing velocity Vin in the direction indicated by arrow D, light-induced embrittled portions are sequentially provided. In other words, light-induced embrittled portions (S and S′) are repeatedly provided in a transverse direction along the split line 115.

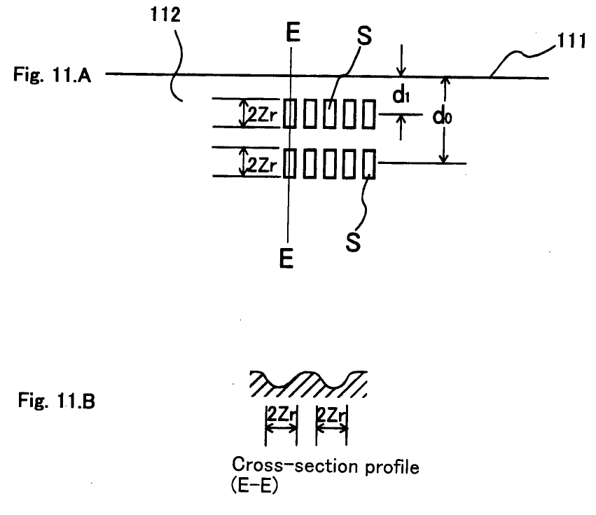

Preferably, there are performed a first internal processing step in which the beam waist 131 is positioned at a depth of d0 from the second surface 111, and subsequently, a second internal processing step in which the beam waist 131 is positioned at d1 (<d0). Through this procedure, a split face 112 is provided with two rows of waist portions S (FIG. 11A). Since each split face has an increased area of indents/protrusions, light extraction efficiency through split faces can be enhanced. Notably, in Example 2 described hereinbelow, the position of the beam waist is sequentially elevated upward (to the second surface 111), and a total of 19 internal processing steps are performed.

FIG. 11B is a cross-section of FIG. 11A cut along the line E-E. When two rows of waist portions are formed, a split face is provided with indents/protrusions also in the thickness direction. One indent has a width almost equivalent to 2Zr, which is a width in the depth direction of a waist portion S. When the Rayleigh range is employed, the Zr represents such a distance that the beam diameter of a single-mode laser beam (Gauss beam) focused by means of a condensing lens falls within 2^{1/2} of the spot diameter of a waist 131. The Rayleigh range Zr is represented by the following equation.
Zr=(4λ/π)(f/2a)² (4)

For example, when a laser beam having a wavelength λ of 1.045 μm is focused at an NA of 0.65, Zr is 2.4 μm (f=4 mm, and 2a=3 mm), whereas when the NA is 0.24, Zr is 59 μm (f=20 mm, and 2a=3 mm). Therefore, the greater the NA, the smaller the Zr, and the smaller the NA, the larger the Zr.

The experiment carried out by the present inventors has revealed that an NA of 0.3 or more is preferred, from the viewpoint of light extraction efficiency through split faces. More preferably, NA is 0.4 or more. Notably, in the case where the grooving step mentioned hereinbelow is performed followed by the internal processing step, an NA of 0.5 or more is preferred. Even when the surface portion of the second surface 111 has been grooved, a laser beam can be effectively focused through the provided groove. When NA is large, reflection of the focused beam by the groove is decreased.

<Grooving Step>

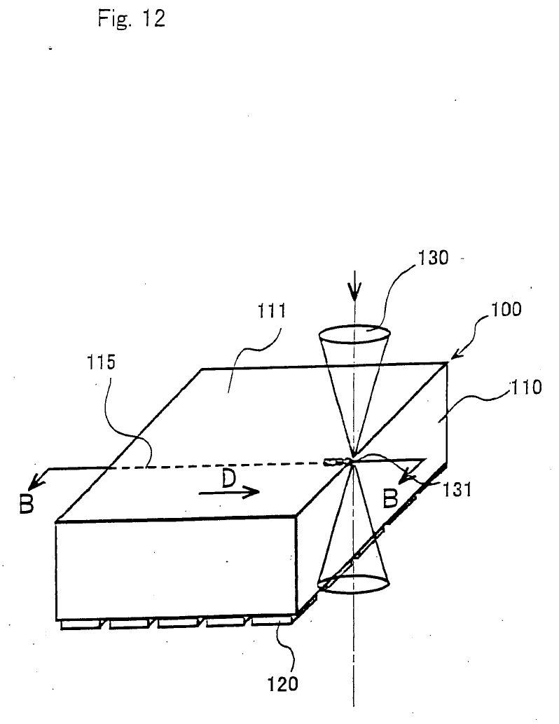

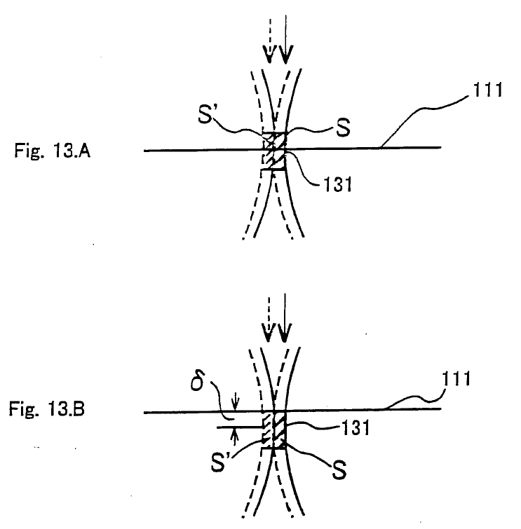

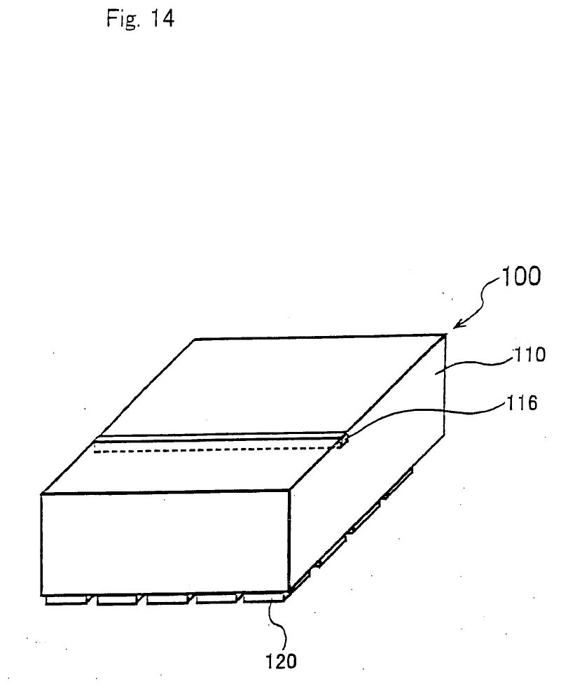

With reference to FIGS. 12 to 14, the grooving step will be described. In FIGS. 12 and 14, numeral 110 denotes a sapphire substrate, and 120 denotes a patterned semiconductor layer. In FIG. 12, 115 denotes a split line indicated by a broken line on the second surface 111 where no semiconductor layer 120 has been stacked. On the first surface 111′ on which the semiconductor layer 120 has been stacked, the split line 115 is provided such that the line passes through the semiconductor layer 120. Prior to carrying out the grooving step, an optical bench is slightly shifted along the Z-axis by means of a drive member of the processing apparatus (FIG. 18) mentioned hereinbelow, whereby the spacing between the second surface 111 of the sapphire substrate and the condensing lens 200 is adjusted. Through the procedure, the beam waist 131 of the laser beam 130 is realized at the second surface 111 or a surface portion of the substrate 110. For example, as shown in FIG. 13B, a waist 131 is positioned at a depth of δ from the second surface 111.

The short pulse laser beam 130 which has been focused by means of the condensing lens 200 is positioned to a waist 131 on the second surface 111 through focusing the condensing lens 200 by use of an illumination source on the second surface 111 of the substrate 110. Then, the condensing lens 200 is shifted toward the second surface 111 of the substrate 1 10 by a predetermined distance of d. Through this procedure, the waist 131 of the short pulse laser beam 130 which has been focused by means of the condensing lens 200 is positioned at a depth of δ from the second surface 111. The d is calculated by equation (1) (d0=δ).

As shown in FIG. 12 and indicated by the broken line, the optical axis OL of the short pulse laser beam 130 is moved relatively with respect to the second surface 111 along the split line 115 predetermined on the second surface 111 of the sapphire substrate 110, toward the arrow D, at a predetermined grooving velocity Vm. In FIG. 13, which is a partial broken cross-section cut along the line B-B of FIG. 12, the movement direction is a left-right direction of the cross-section given in FIG. 13. During the scanning, pulse beam spots of the laser beam 130 which are adjacent to each other are in a contact state or a partially overlapping state. In FIG. 12, these spots on the second surface 111 of the substrate 110, represented by circles (◯), are in contact with one another or partially overlapped. The grooving velocity (scanning speed of laser beam 130) Vm is predetermined so that the spots satisfy the above conditions.

The predetermined grooving velocity Vm is determined so that the waist portions S and S′ adjacent to each other are spatially in a contact state or a partially overlapping state. In order to attain the state, Vm≦2W0·R must be satisfied. When Vm=2W0·R is satisfied, waist portions S and S′ are in a contact state as shown in FIG. 13A, whereas when Vm<2W0·R is satisfied, waist portions S and S′ are overlapped.

FIGS. 13A and 13B are enlarged schematic views of beam waist portions. A continuous line pair represents the shape of a beam waist provided by a pulse beam at a certain time, and a broken line represents the shape of a beam waist provided by a pulse beam of the subsequent frequency. As shown now in FIG. 13A, one pulse beam of the short pulse laser beam 130, which has been focused by a condensing lens (not illustrated), forms a waist portion S on the second surface 111 of the sapphire substrate 110 or in the sapphire substrate 110 from the depth of δ. When the waist portion S is irradiated with a light beam having a high power density of, for example, 5 TW/cm², multi-photon absorption is induced, leading to light-induced embrittlement. When a pulse width is 400 fs, a power density of 5 TW/cm² corresponds to a fluence of 2 J/cm².

For example, when Vm=2W0·R is satisfied, waist portions S and S′ are in a contact state as shown in FIG. 13A, and light-induced embrittled portions are continued to form the groove 16 as shown in FIG. 14. Notably, vapor and particles of the substrate material are emitted from light-induced embrittled portions to the outside in the grooving step. However, since the second surface 111 has not been provided with a semiconductor layer 120, possibly occurring debris do not affect the surface.

In Example 2 mentioned hereinbelow, as shown in FIG. 13A, a first grooving step is performed while a beam waist is positioned on the second surface 111 of the substrate 110, and then further grooving is performed while the beam waist is shifted to a depth of 3 μm from the second surface 111, whereby a deeper groove is formed. By virtue of such a deep groove, splitting can more reliably be performed.

<Splitting Step>

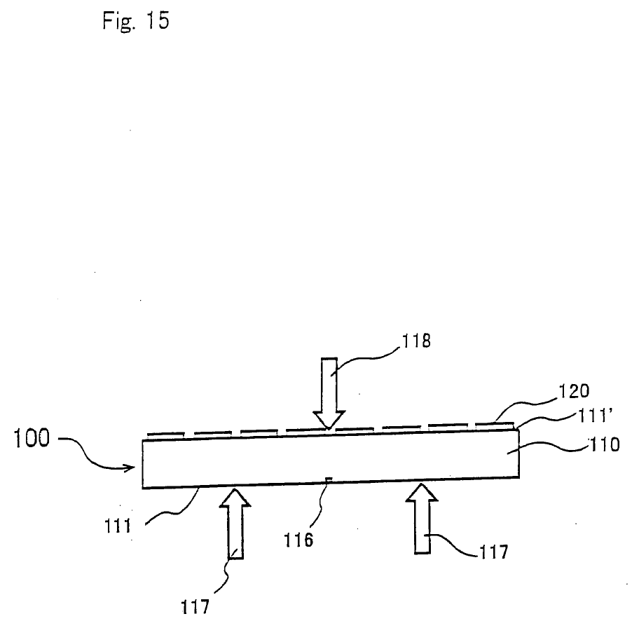

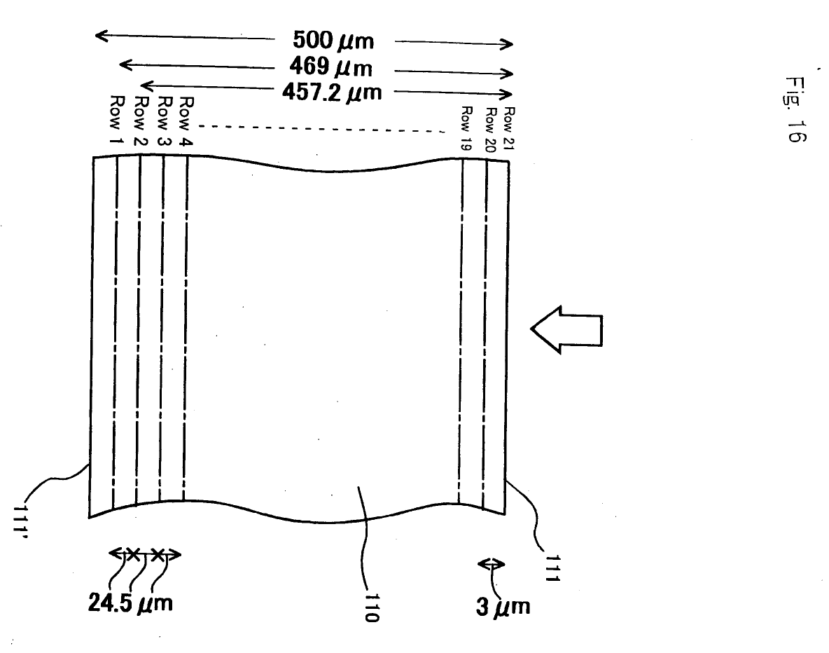

With reference to FIG. 15, there will be described the step of splitting a wafer by the mediation of light-induced embrittled portions provided in the internal processing step and grooves provided in the grooving step. In FIG. 15, reference numeral 110 denotes a sapphire substrate, and 120 denotes a patterned semiconductor layer. Reference numeral 116 denotes a groove provided on the sapphire substrate 110 along the split line. Firstly, as shown in FIG. 15 and indicated by arrows 117, both sides of a wafer along the groove 116, provided along the spit line on the wafer 100 which has been undergone internal embrittling and formation of a grooving of split lines, are sustained or fixed. As shown in FIG. 15 and indicated by arrow 118, a tip of a blade such as a break blade (not illustrated) is caused to abut a portion of the first surface 111′ of the substrate 110 corresponding to the groove 116. The wafer is pressed by the blade to thereby concentrate stress on the groove 116, whereby the wafer 100 can be simply and readily split along the split line.

Then, with reference to FIG. 18, a splitting apparatus for carrying out the splitting method of the present invention will be described. The splitting apparatus has an optical system including the following: a laser apparatus 150 for generating a laser beam 130, a shutter 154 for controlling ON-OFF of the laser beam 130, a dichroic mirror 155 which transmits the laser beam 130, and a condensing lens 200 for focusing the laser beam 130 which has passed through the dichroic mirror 155. The splitting apparatus has a mechanical system including the following: a table 157 on which a wafer 100, which is a workpiece and to which the laser beam 130 focused by the condensing lens 200 is caused to enter in the Z-axis direction, is placed; an X-axis stage 171 for moving the table 157 in the X-axis direction; a Y-axis stage 172 for moving the table 157 in the Y-axis direction, which is normal to the X-axis direction; and a Z-axis stage 173 for moving the table 157 in the Z-axis direction, which is normal to the X-axis and Y-axis directions. The splitting apparatus also has a personal computer 180 for controlling the systems.

The splitting apparatus further includes an inspection light source 163 for emitting visible light for illuminating the wafer 100 placed on the table 157 for inspection; a half mirror 156 for bending the visible light emitted from the inspection light source 163 by 90° so as to cause the light to enter the dichroic mirror 155; and a CCD camera 162 for picking up the image of the wafer 100 by the mediation of the condensing lens 200, the dichroic mirror 155, and the half mirror 156.

The splitting apparatus further includes an optical bench 164 which holds the laser apparatus 150, the shutter 154, the dichroic mirror 155, the condensing lens 200, the half mirror 156, the inspection light source 163, and the CCD camera 162; and a drive unit 161 for driving the optical bench 164 in the Z-axis direction.

The shutter 154, the inspection light source 163, the CCD camera 162, and the drive unit 161 are connected to the control personal computer 180. The personal computer 180 controls ON-OFF of the shutter 154 and the inspection light source 163, processing of the images picked up by the CCD camera 162, and driving of the drive unit 161. Thus, according to a command issued by the control personal computer 180, the waist 131 (focus) of the laser beam 130 is imaged by the CCD camera 162, and the image can be observed on the monitor of the control personal computer 180.

The laser apparatus 150 includes an oscillating module 151; a fiber 153 through which the laser beam oscillated by the oscillating module 151 propagates; an amplifying module 152 for amplifying the laser beam propagating through the fiber 153; and a laser controller 154 for controlling output, pulse width, and frequency of the laser beam provided by the oscillating module 151. The laser controller 154 is connected to the personal computer 180 and functions by a command issued by the personal computer 180. The oscillating module 151 includes a mode-lock fiber laser co-doped with Er and Yb; a fiber expander for receiving the pulse laser beam oscillated by the fiber laser and outputting the expanded pulse laser beam; a pulse selector for receiving the expanded pulse laser beam and selecting pulses; and a fiber pre-amplifier for receiving the expanded and selected pulse laser beam and outputting an amplified pulse laser beam. The amplifying module 152 includes a fiber main amplifier for receiving the pulse laser beam provided by the oscillating module 151 via the fiber 153 and further amplifying the beam; and a compressor for receiving the amplified pulse laser beam and outputting a compressed pulse laser beam. The amplifying module 152 is affixed to the optical bench 164 such that the laser beam 130 is emitted in the Z-axis direction. The amplifying module 152 emits a laser beam L having a wavelength of 1,045 nm, a mean output power of 250 mW, a pulse width of 400 to 600 fs, and a repetition frequency of 50 to 200 kHz.

The laser apparatus 150 is not limited to the aforementioned one, and any laser apparatus may be employed, so long as the apparatus attains a wavelength of 300 to 1,800 nm, a pulse width of 10 fs to 10 ps, and a repetition frequency of 50 kHz to 10 MHz. For example, a regeneration-amplification Ti: sapphire laser apparatus or a similar laser apparatus may also be employed. The laser apparatus 150 preferably outputs a laser beam having a wavelength of 700 to 1,600 nm, a pulse width of 50 fs to 2 ps, and a repetition frequency of 50 to 300 kHz. When a laser beam having the aforementioned properties is employed, absorption of light by indents/protrusions of split faces is decreased, whereby light extraction efficiency through split faces can be further enhanced.

Next, the operational procedure of the aforementioned splitting apparatus will be described. Firstly, the shutter 154 is closed, and the laser apparatus 150 is operated at a predetermined repetition frequency. Then, the shutter 154 is opened, and the oscillating module 151 is controlled by means of the controller 154 such that the laser beam 130 transmitted through the condensing lens 200 has a predetermined pulse energy.

Subsequently, the shutter 154 is closed, and a wafer 100 is placed on the table 157 such that the split line 115 is oriented in the X-axis direction. Then, the inspection light source 163 is activated, and the X-axis stage 171 and the Y-axis stage 172 are moved so that the focus is positioned to the split line 115 on the second surface 111, while the second surface 111 of the wafer 100 is observed by means of the CCD camera 162. The optical bench 164 is slightly moved in the Z-axis direction by means of the drive unit 161.

Subsequently, the optical bench 164 is moved downwardly by means of the drive unit 161 to the second surface 111 such that the waist 131 is positioned at a predetermined depth d0 from the second surface 111.

Subsequently, the shutter 154 is opened, and the wafer 100 is moved by means of the X-axis stage 171 in the X-axis direction at a predetermined velocity Vin, while the waist is irradiated with the focused laser beam 130. After the wafer 100 has been moved by a predetermined distance, the shutter 154 is closed.

Subsequently, the optical bench 164 is moved upward by means of the drive unit 161 from the second surface 111 such that the waist 131 is positioned at a predetermined depth d1 (<d0) from the second surface 111.

Subsequently, the shutter 154 is opened, and the wafer 100 is moved by means of the X-axis stage 171 in the X-axis direction at a predetermined velocity Vin, while the waist is irradiated with the focused laser beam 130. After the wafer 100 has been moved by a predetermined distance, the shutter 154 is closed.

Subsequently, the optical bench 164 is moved upward by means of the drive unit 161 from the second 111 such that the waist 131 is positioned at the first surface 111′.

Subsequently, the shutter 154 is opened, and the wafer 100 is moved by means of the X-axis stage 171 in the X-axis direction at a predetermined velocity Vm, while the waist is irradiated with the focused laser beam 130. After the wafer 100 has been moved by a predetermined distance, the shutter 154 is closed.

### EXAMPLE 2

As shown in FIG. 16, internal embrittling steps 1 to 19 were sequentially performed. Then, steps 20 and 21 were performed so as to form a groove. The process was performed under the following conditions.
Work piece: sapphire single crystal (thickness: t=500 μm)
Laser apparatus: Er, Yb-codoped mode-lock fiber laser base femtosecond laser apparatus
Wavelength: 1.045 μm
Pulse width: 400 fs
Pulse repetition frequency: 100 kHz
Condensing lens: numerical aperture of 0.65, and focal length of 4 mm
Pulse energy after passage of condensing lens: 1.5 μJ
Fluence at beam waist: 160 J/cm² (calculated)
Power density at beam waist: 400 TW/cm² (calculated)
Laser beam incident face: c-plane of the sapphire crystal (second surface 111 in FIG. 16)
Laser beam incident direction: normal to C plane (direction indicated by the white arrow in FIG. 16)
Number of internal embrittling steps: 19 rows (rows 1 to 19 in FIG. 16)
Position of 1st-row waist: depth (thickness direction) of 469 μm from the incident face (Calculated waste position. The value was obtained when the focus of the condensing lens was positioned at the incident face, then the condensing lens was moved to the incident face by 268 μm)
Spacing of internal embrittling: 24.5 μm (Calculated inter-waist spacing. The value was obtained
when the condensing lens was moved from the incident face by 14 μm after completion of the previous internal embrittling step)
Velocity of internal embrittling Vin: 400 mm/s
Grooving steps: 2 rows (rows 20 and 21 in FIG. 16)
Position of row-20 waist: incident face
Position of row-21 waist: position obtained when the focus of the condensing lens was positioned at the incident face, then the condensing lens was moved to the incident face by 3 μm
Velocity of grooving Vm: 200 mm/s

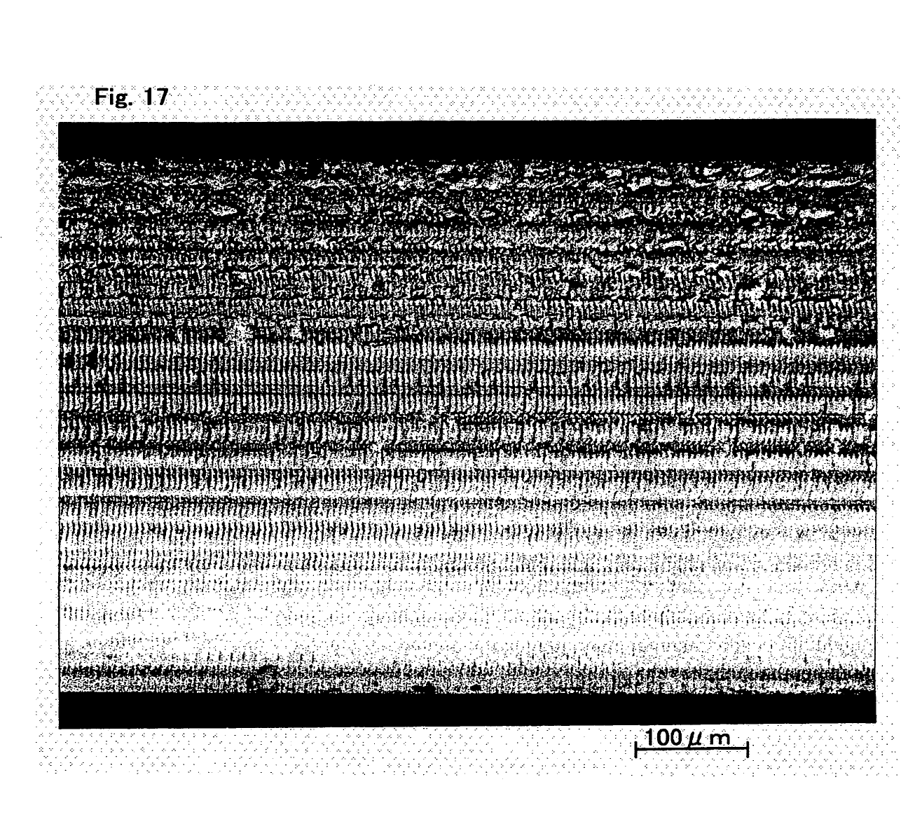

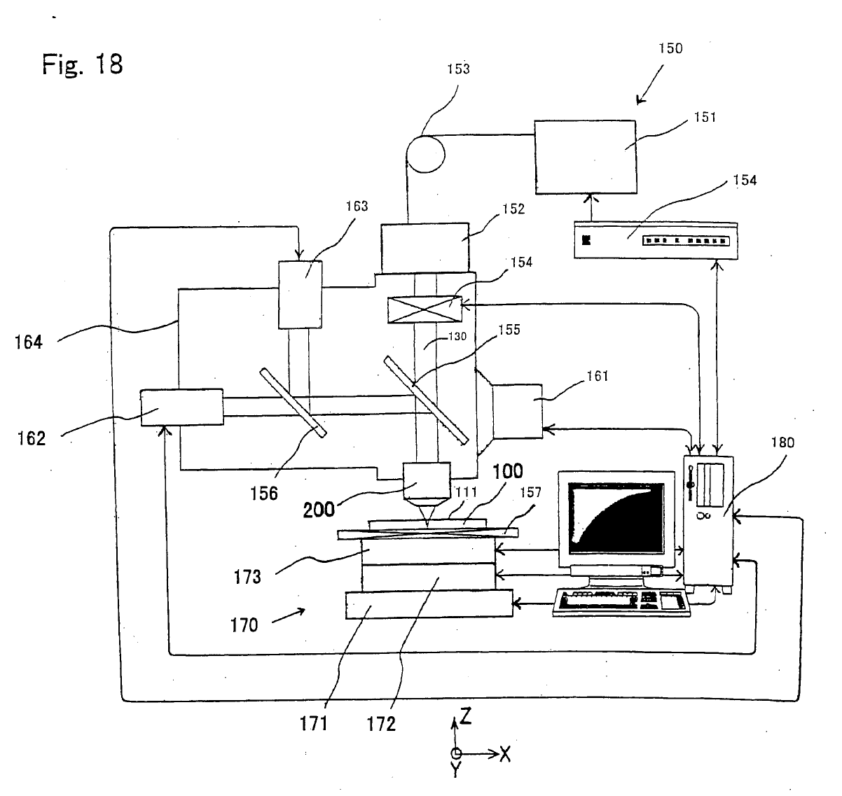

FIG. 17 is a microscopic image of a split face of a sapphire substrate. The substrate was subjected to internal embrittling and grooving under the aforementioned conditions, and split by means of a breaking blade which was caused to abut the wafer and pressed. In the image, white areas having a considerable length in the depth direction show light-induced embrittled portions. The light-induced embrittled portions are discretely arranged and isolated by non-processed areas (black portions). The white portions assume the form of indents (in the forward-backward direction in the image; i.e., the direction normal to the split face). The indents were found to have a depth of about 1 μm. The pitch of the indents in the laser scanning direction was found to be 4 to 5 μm.

The light extraction efficiency through the split face was determined. Of the four side faces of the wafer (i.e., the second surface 111 and the first surface 111′ are excluded), three faces were mirror-polished, and the remaining face was measured in terms of light extraction efficiency. Specifically, a blue LED (surface-mounting type) was bonded to the first surface 111′ by use of a UV-curable adhesive (refractive index: 1.55). The amount of light emitted through the measurement face was determined. As a result, the light extraction efficiency was found to be enhanced by 6%.

What is claimed is:

1. A method for separating semiconductor light-emitting devices formed on a substrate, said method comprising
focusing a pulse laser beam having a pulse width less than 10 ps in said substrate, to thereby cause multi-photon absorption in said substrate;
forming a surface structurally changed portion by means of said pulse laser beam along a split line predetermined on a surface of said substrate;
forming internal structurally changed portions through said pulse laser beam at a predetermined depth of said substrate on a predetermined split face, said internal structurally changed portions being discontinuous in a direction of said predetermined split line; and
applying an external force to thereby form a split face along said surface structurally changed portion and said discontinuous internal structurally changed portions, whereby said semiconductor light-emitting devices are separated from one another.

2. A method for separating semiconductor light-emitting devices as described in claim 1, wherein said surface structurally changed portion is discontinuously separated in plural sections along said split line.

3. A method for separating semiconductor light-emitting devices as described in claim 1, wherein said surface structurally changed portion is substantially continuous to form a groove along said split line.

4. A method for separating semiconductor light-emitting devices as described in claim 1, wherein two or more rows of said discontinuous internal structurally changed portions is formed along a depth direction of said substrate.

5. A method for separating semiconductor light-emitting devices as described in claim 1, wherein additional internal structurally changed portions are formed along said split line through a pulse laser beam such that said additional internal structurally changed portions are connected to said surface structurally changed portion in a depth direction, and subsequently, an external force is applied.

6. A method for separating semiconductor light-emitting devices as described in claim 3, wherein additional internal structurally changed portion are formed through a pulse laser beam such that said internal structurally changed portions are continuous along said split line and connected to said continuous groove in the depth direction, and subsequently, an external force is applied.

7. A method for separating semiconductor light-emitting devices as described in claim 4, wherein additional internal structurally changed portions are formed along said split line through a pulse laser beam such that said additional internal structurally changed portions are connected to said surface structurally changed portion in a depth direction, and subsequently, an external force is applied.

8. A method for separating semiconductor light-emitting devices as described in claim 1, wherein said radiated laser beam is a linearly polarized laser beam having an electric field component parallel to said predetermined split face or an elliptically polarized laser beam exhibiting a trajectory of the electric field component that forms an ellipse having a longer axis parallel to said predetermined split face.

9. A method for separating semiconductor light-emitting devices as described in claim 4, wherein said radiated laser beam is a linearly polarized laser beam having an electric field component parallel to said predetermined split face or an elliptically polarized laser beam exhibiting a trajectory of the electric field component that forms an ellipse having a longer axis parallel to said predetermined split face.

10. A method for separating semiconductor light-emitting devices as described in claim 5, wherein said radiated laser beam is a linearly polarized laser beam having an electric field component parallel to said predetermined split face or an elliptically polarized laser beam exhibiting a trajectory of the electric field component that forms an ellipse having a longer axis parallel to said predetermined split face.

11. A method for separating semiconductor light-emitting devices as described in claims 1, wherein said laser beam is radiated through an objective lens having a numerical aperture of 0.5 or more.

12. A method for separating semiconductor light-emitting devices as described in claims 4, wherein said laser beam is radiated through an objective lens having a numerical aperture of 0.5 or more.

13. A method for separating semiconductor light-emitting devices as described in claims 5, wherein said laser beam is radiated through an objective lens having a numerical aperture of 0.5 or more.

14. A method for separating semiconductor light-emitting devices as described in claims 8, wherein said laser beam is radiated through an objective lens having a numerical aperture of 0.5 or more.

15. A method for separating semiconductor light-emitting devices as described in claim 1, wherein said substrate is a sapphire substrate.

16. A method for separating semiconductor light-emitting devices as described in claim 14, wherein said substrate is a sapphire substrate.

17. A method for separating semiconductor light-emitting devices as described in of claim 1, wherein said internal structurally changed portions each includes a head portion which is formed at a focal site of said pulse laser beam and which has a diameter parallel to a substrate surface of 1.5 μm or more, and a leg portion which extends from said head portion along said radiated pulse laser beam through filamentation and which has a diameter parallel to said substrate surface of 0.8 μm or more.

18. A method for separating semiconductor light-emitting devices as described in of claim 4, wherein said internal structurally changed portions each includes a head portion which is formed at a focal site of said pulse laser beam and which has a diameter parallel to a substrate surface of 1.5 μm or more, and a leg portion which extends from said head portion along said radiated pulse laser beam through filamentation and which has a diameter parallel to said substrate surface of 0.8 μm or more.

19. A method for separating semiconductor light-emitting devices as described in of claim 5, wherein said internal structurally changed portions each includes a head portion which is formed at a focal site of said pulse laser beam and which has a diameter parallel to a substrate surface of 1.5 μm or more, and a leg portion which extends from said head portion along said radiated pulse laser beam through filamentation and which has a diameter parallel to said substrate surface of 0.8 μm or more.

20. A method for separating semiconductor light-emitting devices as described in of claim 8, wherein said internal structurally changed portions each includes a head portion which is formed at a focal site of said pulse laser beam and which has a diameter parallel to a substrate surface of 1.5 μm or more, and a leg portion which extends from said head portion along said radiated pulse laser beam through filamentation and which has a diameter parallel to said substrate surface of 0.8 μm or more.

21. A method for separating semiconductor light-emitting devices, including splitting a wafer into individual semiconductor light-emitting device chips, said wafer comprising a transparent substrate having a first surface, and a second surface parallel to the first surface, and a semiconductor layer containing a light-emitting layer and deposited on the first surface of said transparent substrate, wherein the method comprises
a first internal processing step including
causing a pulse laser beam having a wavelength ensuring optical transparency with respect to said wafer to enter said wafer through said first or second surface serving as an incident face by the mediation of a condensing lens, while a focus of the condensing lens is adjusted such that a waist, which is a pulse laser beam focused portion, is present in said wafer;
shifting an optical axis of said pulse laser beam relative to an incident face and along an imaginary split line predetermined on said wafer such that waists formed from said pulse beams provided by said pulse laser beam are spatially separated from one another; and
at every incidence of said pulse beam of said pulse laser beam on said incident face, embrittling a portion of said wafer corresponding to said waist through multi-photon absorption, to thereby form discontinuous light-induced embrittled portions; and
a grooving processing step including
adjusting said focus of said condensing lens such that a waist formed by said pulse laser beam is present in a surface portion of said incident face of said wafer;
shifting said optical axis of said pulse laser beam relative to said incident face and along said split line such that waists formed from said pulse beams provided by said pulse laser beam are spatially connected to or overlapped with one another; and
at every incidence of the pulse beam of the pulse laser beam on the incident face, embrittling a portion of the wafer corresponding to the waist through multi-photon absorption, to thereby form a continuous groove, wherein
each of the semiconductor light-emitting device chips has a split face provided with indents/protrusions.

22. A method for separating semiconductor light-emitting devices as described in claim 21, which said method further comprises
a second internal processing step including
adjusting said focus of said condensing lens such that a waist is present between said light-induced embrittled portions formed in said first internal processing step and said incident face;
shifting said optical axis of said pulse laser beam relative to said incident face and along an imaginary split line predetermined on said wafer such that waists formed from said pulse beams provided by said pulse laser beam are spatially separated from one another; and
at every incidence of said pulse beam of said pulse laser beam on said incident face, embrittling a portion of said wafer corresponding to said waist through multi-photon absorption, to thereby form discontinuous light-induced embrittled portions.

23. A method for separating semiconductor light-emitting devices as described in claim 21, wherein said condensing lens has a numerical aperture of 0.3 or more.

24. A method for separating semiconductor light-emitting devices as described in claim 22 wherein said focus of said condensing lens is adjusted such that upper portions of said light-induced embrittled portions formed in said second internal processing step and a bottom of said groove formed in said grooving step are connected to one another.

25. A semiconductor light-emitting device, including a transparent substrate having a first surface, and a second surface parallel to the first surface, and a semiconductor layer containing a light-emitting layer and deposited on said first surface, wherein said semiconductor light-emitting device separated from a wafer has a split face provided with indents/protrusions.
